(19) United States
(12) Patent Application Publication
(10) Pub. No.: US 2003/0232283 A1
(43) Pub. Date: Dec. 18, 2003

(54) Method for forming a photoresist pattern on a semiconductor substrate

(76) Inventors: Chen-Cheng Yung, Hsinchu Hsien (TW); Ming-Chuan Wang, Kaohsiung Hsien (TW); Chang-Hao Yang, Nan-Tou Hsien (TW)

Correspondence Address: NEEDLE & ROSENBERG, P.C., SUITE 1000, 999 PEACHTREE STREET, ATLANTA, GA, 30309-3915, US

(21) Appl. No.: 10/177,634

(22) Filed: Jun. 18, 2002

(51) Int. Cl. G03F 7/16; G03F 7/20; G03F 7/38

(52) U.S. Cl. 430/311; 430/330; 430/950; 430/327

(57) ABSTRACT

A method for forming photoresist layers on a substrate. First, a first photoresist material is coated on the substrate. Next, a second photoresist material is coated on the first photoresist material before the first photoresist material is baked. Thereafter, the substrate is baked at 100˜140° C. for 50˜80 seconds to simultaneously form a first photoresist layer and a second photoresist layer thereon. The method further includes a step of cooling the first and the second photoresist layers to room temperature after the baking is performed.

### BACKGROUND OF THE INVENTION

1. Field of the Invention

The present invention relates to semiconductor technology, and more particularly to a method for forming a photoresist pattern on a semiconductor substrate in lithography.

2. Description of the Related Art

In semiconductor processing, lithography is frequently used for reproducing circuits and structures on a semiconductor substrate. As a first step in lithography, a photoresist layer is formed on a semiconductor substrate such that an image can be projected and developed on the substrate.

The photoresist material is a liquid that is coated in a very thin layer on top of the semiconductor substrate by a spin coating apparatus, and then baking is performed to cure the photoresist material by hot plates. In order to prevent the standing wave effect and the photoresist material poison issue, a top anti-reflection layer (ARL) is frequently deposited on the photoresist layer for defining a specific feature of the circuit. FIGS. 1a to 1c are cross-section illustrating a conventional method for forming a photoresist pattern on a semiconductor substrate.

In FIG. 1a, a substrate 10 such as a semiconductor substrate is provided. A photoresist material (not shown) is coated on the substrate 10 by a spin coating apparatus, and then a first baking 11 is performed to form a photoresist layer 12 by hot plates (not shown).

In FIG. 1b, after the substrate 10 covered by a photoresist layer 12 is cooled to room temperature, another photoresist material such as an anti-reflection material is coated on the photoresist layer 12. Also, a second baking 13 is performed again to form an ARL 14 by hot plates. The anti-reflection layer 14 is a top ARL to prevent the standing wave effect and the photoresist layer 12 poison issue.

In FIG. 1c, lithography is performed to the photoresist layer 12 and the top ARL 14 to remove the top ARL 14 and to form a photoresist pattern 12 on the substrate 10.

In the conventional method, however, baking is performed twice to cure the photoresist material and anti-reflection material, respectively, to form the photoresist layer 12 and the top ARL 14. That is, many hot plates are required and the lithography steps are increased for the layers 12, 14. As a result, the manufacturing cost is increased and the throughput is reduced.

### SUMMARY OF THE INVENTION

It is therefore an object of the present invention to provide a method for forming photoresist layers on a substrate without baking twice to reduce the manufacturing cost.

Another object of the present invention is to provide a method for defining a photoresist pattern on a substrate to increase throughput by simplifying the steps of lithography are.

According to an aspect of the invention, there is provided a method for forming photoresist layers on a substrate, which includes the steps of: coating a first photoresist material on the substrate; coating a second photoresist material on the first photoresist material before baking the first photoresist material; and baking the substrate to simultaneously form a first photoresist layer and a second photoresist layer over the first photoresist layer. The method further includes a step of cooling the substrate to room temperature after the baking step.

According to another aspect of the invention, there is provided a method for forming a photoresist pattern on a substrate, which includes the steps of: coating a photoresist material on the substrate; coating an anti-reflection material on the photoresist material before baking the photoresist material; baking the substrate to simultaneously form a photoresist layer and an anti-reflection layer over the photoresist layer; performing an exposure on the anti-reflection layer and the photoresist layer by a patterning mask; and performing a development on the anti-reflection layer and the photoresist layer to form a photoresist pattern on the substrate. The method further includes a step of cooling the substrate to room temperature after the baking step.

### BRIEF DESCRIPTION OF THE DRAWINGS

The present invention can be more fully understood by reading the subsequent detailed description in conjunction with the examples and references made to the accompanying drawings, wherein:

FIGS. 1a to 1c are sectional diagrams showing a method for forming a photoresist pattern on a semiconductor substrate according to the prior art.

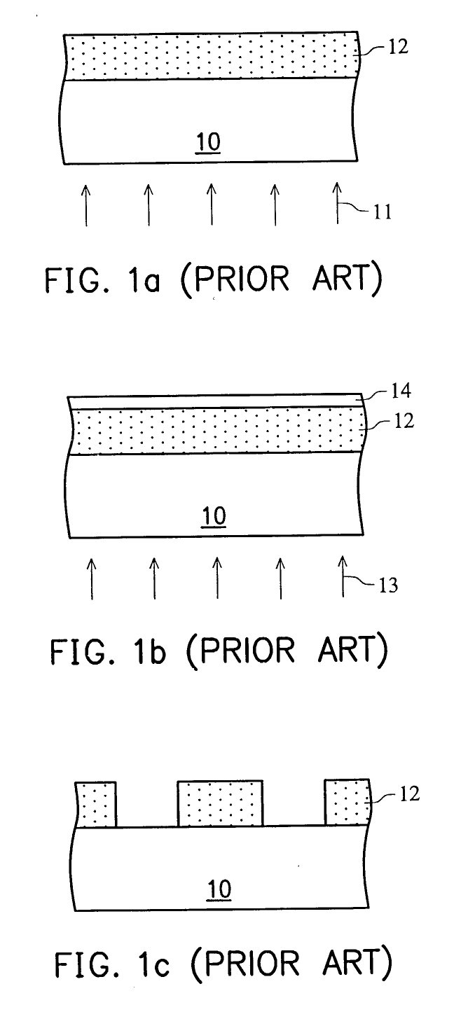

FIGS. 2a to 2c are sectional diagrams showing a method for forming a photoresist pattern on a semiconductor substrate according to the present invention.

FIG. 3a is a trend chart showing the relationship between the yield (%) and lot number (#) according to the present invention.

FIG. 3b is a trend chart showing the relationship between the yield (%) and lot number (#) according to the prior art.

### DETAILED DESCRIPTION OF THE PREFERRED EMBODIMENT

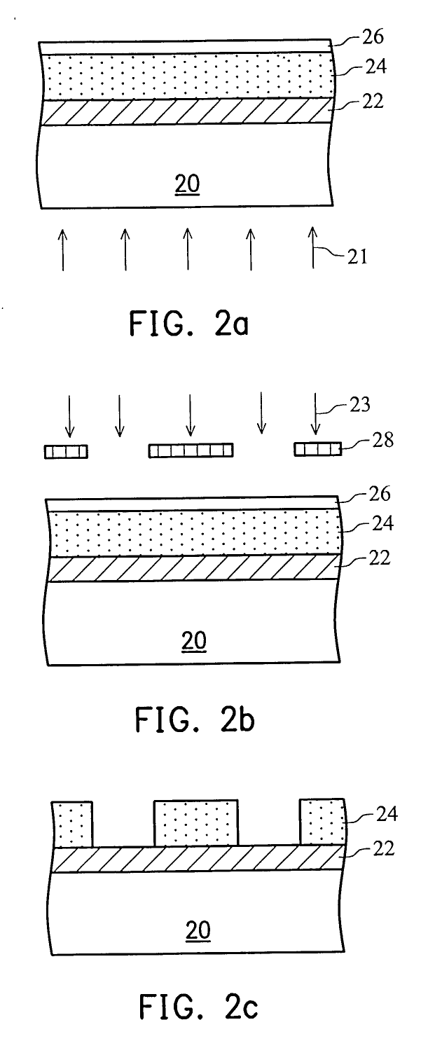

FIGS. 2a to 2c are sectional diagrams showing a method for forming a photoresist pattern on a semiconductor substrate according to the present invention.

In FIG. 2a, a substrate 20 is provided. The substrate 20 is understood to possibly include a semiconductor wafer, active and passive devices formed within the wafer. Herein, a smooth substrate 20 is shown to simplify the diagram. A layer to be defined 22 is formed on the substrate 20 by deposition. The layer to be defined 22 can be a conductive layer such as a polysilicon layer, or a dielectric layer such as a silicon oxide layer. Thereafter, a first photoresist material (not shown) is coated on the substrate 20 by a spin coating apparatus (not shown), and a second photoresist material (not shown) is coated on the first photoresist material by a spin coating apparatus before the first photoresist material is baked. In the present invention, for example, the first photoresist material can be a chemical amplified resist (CAR) material and the second photoresist material can be an organic anti-reflection material.

Next, hot plates (not shown) are used to bake 21 the substrate 20 to simultaneously form a photoresist layer 24 and a top ARL 26 over the photoresist layer 24. In the present invention, the baking 21 is performed at 100˜140° C. for 50˜80 seconds.

In FIG. 2b, after the substrate 20 covered by the layers 26, 24 is cooled to room temperature, an exposure 23 is performed on the layers 26, 24 using a patterned mask 28. Subsequently, a development is performed on the layers 26, 24 to remove the top ARL 26 and to form a photoresist pattern 24 on the substrate 20, as shown in FIG. 2c.

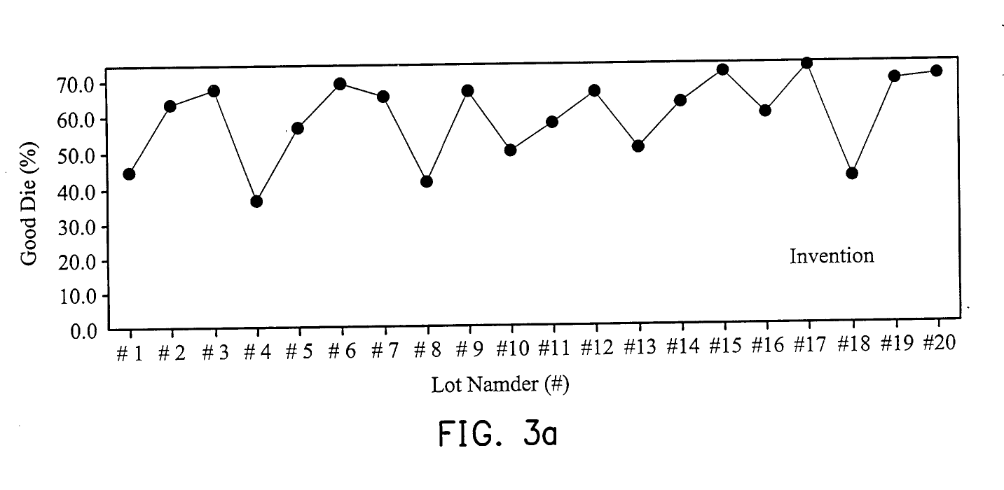

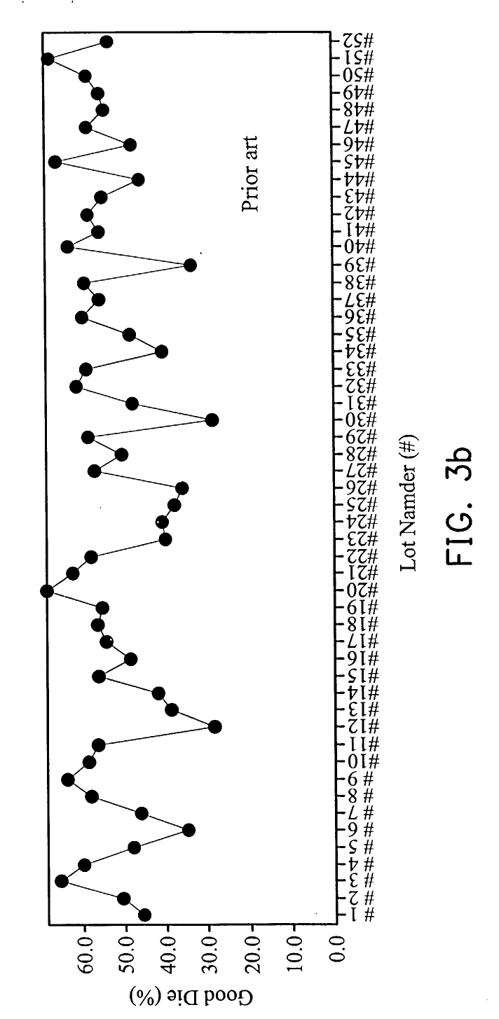

FIGS. 3a and 3b are trend charts showing the relationship between the yield (%) and lot number (#) according to the present invention and the prior art, respectively. As shown in FIGS. 3a and 3b, while the present invention uses one baking, the average yield (about 60%) is higher than that (about 52%) of the prior art.

Therefore, compared with the conventional method for forming a photoresist pattern on a substrate, the present invention just uses one baking to cure the photoresist material. It is an advantage to reduce the manufacturing cost by reducing the numbers of hot plates. Moreover, the steps of lithography are simplified to increase the throughput.

Finally, while the invention has been described by way of example and in terms of the preferred embodiment, it is to be understood that the invention is not limited to the disclosed embodiment. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A method for forming photoresist layers on a substrate, comprising the steps of:
coating a first photoresist material on the substrate;
coating a second photoresist material on the first photoresist material before baking the first photoresist material; and
baking the substrate to simultaneously form a first photoresist layer and a second photoresist layer over the the first photoresist layer.

2. The method as claimed in claim 1, further comprising a step of forming a polysilicon layer on the substrate before the step of coating the first photoresist material.

3. The method as claimed in claim 1, further comprising a step of cooling the substrate to room temperature after the step of baking.

4. The method as claimed in claim 1, wherein the second photoresist layer is an anti-reflection coating.

5. The method as claimed in claim 1, wherein the substrate is a silicon substrate.

6. The method as claimed in claim 1, wherein the baking is performed at 100˜140° C.

7. The method as claimed in claim 1, wherein the baking is performed for 50˜80 seconds.

8. The method as claimed in claim 4, wherein the second photoresist material is an organic material.

9. A method for forming a photoresist pattern on a substrate, comprising the steps of:
coating a photoresist material on the substrate;
coating an anti-reflection material on the photoresist material before baking the photoresist material;
baking the substrate to simultaneously form a photoresist layer and an anti-reflection layer over the photoresist layer;
performing an exposure on the anti-reflection layer and the photoresist layer by a patterning mask; and
performing a development on the anti-reflection layer and the photoresist layer to form a photoresist pattern on the substrate.

10. The method as claimed in claim 9, wherein the substrate is a semiconductor substrate covered by a conductive layer or a dielectric layer.

11. The method as claimed in claim 10, wherein the conductive layer is a polysilicon layer.

12. The method as claimed in claim 9, further comprising a step of cooling the substrate to room temperature after the step of baking.

13. The method as claimed in claim 9, wherein the anti-reflection material is an organic material.

14. The method as claimed in claim 9, wherein the baking is performed at 100˜140° C.

15. The method as claimed in claim 9, wherein the baking is performed for 50˜80 seconds.
